(19) United States
(12) Patent Application Publication
(10) Pub. No.: US 2011/0061709 A1
(43) Pub. Date: Mar. 17, 2011

(54) Structural element for a solar panel, and structure comprising such an element

(76) Inventor: Denis Payan, Mervilla (FR)

(21) Appl. No.: 12/801,376

(22) Filed: Jun. 4, 2010

(30) Foreign Application Priority Data
Jun. 5, 2009 (FR) 09 53717

(51) Int. Cl. H01L 31/042; H01B 5/14

(52) U.S. Cl. 136/244; 174/126.4

(57) ABSTRACT

The invention relates to a structural element for a solar panel, comprising at least one layer of dielectric material, characterized in that it comprises conductive means, which are in contact with said layer of dielectric material, and an electrical connection means for connecting the conductive means to the earth of said structure.

The present invention relates to a structural element for a solar panel, of the type comprising at least one layer of dielectric material.

Solar panels commonly comprise a conductive structural part which is to receive a network of solar cells. The conductive structural part is covered with at least one layer of dielectric material. Adhesion means are also provided between the conductive structural part and said dielectric material.

Such a structure for a solar panel is known, in which the conductive structure is commonly produced in the form of a honeycomb structure made of aluminium which is adhesively bonded between two skins composed of carbon fibres. This conductive structure is connected to the earth of the satellite in order to ensure equipotentiality, the solar cells being fixed to the layer of dielectric material.

In order to carry out its structural function, the honeycomb structure is reinforced on both its faces by carbon fibres embedded in an epoxy-type structural adhesive.

The layer of dielectric material commonly used is made of a polyimide polymer, and it is commonly marketed under the name Kapton® or Upilex®.

The layer of dielectric material is fixed to the conductive structure. It is therefore in contact with the epoxy adhesive serving as binder for the carbon fibres covering the sheet, which adhesive is not particularly conductive.

The photoelectric cells are fixed in the form of a matrix to the layer of dielectric material of the structure so produced, thus forming a structure for a solar panel.

When such a structure is used in space, the layers of dielectric material accumulate charges.

Such charges can prove to be dangerous for the operation of the solar panel because they cause electrostatic discharges in the region of the dielectric layers or the adjacent metal coatings, which can be at the origin of considerable degradation of the solar panel.

In a current mode of operation it has been found that the accumulated charges were partially discharged into space naturally, by photoemission when the panel is illuminated. They are also partially discharged by migrating through the epoxy adhesive used to fix the layer of Kapton® to the carbon fibres and/or for embedding the carbon fibres of the structure of the panel, as is described especially in document U.S. Pat. No. 4,534,998.

Accordingly, the charges naturally flow to the conductive structure whose function is to ensure equipotentiality.

The epoxy adhesive, whose initial function was simply to connect the layer of dielectric material to the plane of carbon fibres and/or to hold reinforcing elements on the metal sheet, has therefore been assigned an additional function of discharging the charges which accumulate on the layer of dielectric material.

However, it has been found that the epoxy adhesive is unable to perform that function under particular conditions, especially when the solar panel is in positions of solar eclipse, because it becomes very cold and consequently electrically insulating.

In particular, when the solar panel is fixed to a satellite placed in geostationary orbit (GEO orbit) around the earth, it is wholly or partially deprived of light from the sun at the time of the vernal or autumnal equinoxes.

It has been calculated that the total duration of this light deprivation of the solar panel is approximately 1 hour per day for 22 days of the year.

Under such light deprivation conditions, the temperature can reach −180° C.
It is during these short eclipse exit periods that the solar panels undergo numerous degradations.

Moreover, the same phenomenon of the accumulation of charges has also been found on the protective glasses of the photoelectric cells of solar panels.

When solar panels capture light, the charges accumulated on the glasses are discharged into space by photoemission or at least partially by conduction through the silicone adhesive which holds the glass on the cell.

However, in solar eclipse situations, the charges accumulated on the glass are not discharged sufficiently and can also be at the origin of degradation of the solar panel, because the adhesive becomes insulating at a temperature below 30° C.

The object of the invention is to remedy the disadvantages of epoxy or silicone adhesives in such situations by providing the function of discharging the charges that accumulate on a layer of dielectric material, whether it be composed of a layer of Kapton® or of a sheet of protective glass, even at very low temperatures.

To that end, the invention relates to a structural element for a solar panel of the above-mentioned type, which is characterized in that it comprises conductive means, which are in contact with said layer of dielectric material, and electrical connection means for connecting the conductive means to the earth of said structure.

When so produced, the structural element serves to discharge the charges accumulated in said layer of dielectric material, whether that layer be, for example, a layer of polyimide polymer or a sheet of protective glass of a photoelectric cell, and under any temperature conditions. On the one hand, the conductive means are in contact with the layer of dielectric material and, on the other hand, there is a potential difference between the charged layer of dielectric material and the earth of the structure.

According to embodiments which will be described and illustrated hereinbelow, the structural element according to the invention can have the following features, taken separately or in combination:

said conductive means comprise a grid of metal wires or conductors;
said metal grid is positioned against a surface of said layer of dielectric material and held by adhesion means, or is vacuum deposited;
said grid is arranged between two layers of dielectric material;
said conductive means comprise a conductive coating which covers a surface of said layer of dielectric material at least partially;
said layer of dielectric material is made of polyimide polymer;
said layer of dielectric material is a sheet of protective glass for a photoelectric cell;
said electrical connection means is a conductive element.

The invention relates also to a structure for a solar panel, characterized in that it comprises at least one structural element as defined hereinbefore.

Finally, the invention relates to a solar panel comprising a structure as defined above.

The invention will better be understood upon reading the exemplary embodiments which will now be described with reference to the accompanying figures, in which:

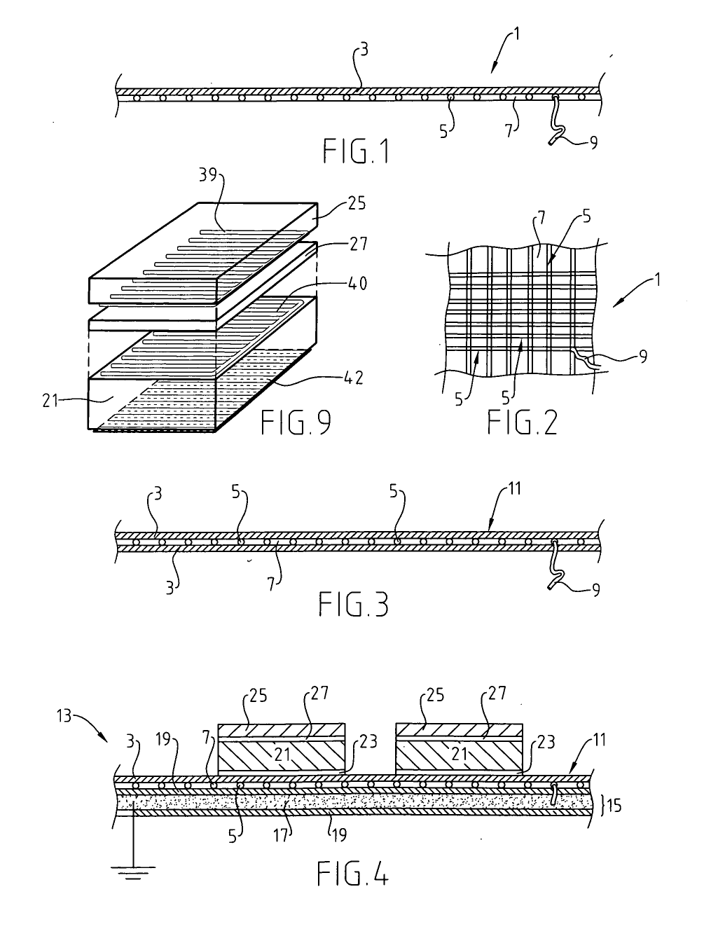

FIG. 1 is a cutaway view of a first structural element according to the invention;

FIG. 2 is a bottom view of the structural element shown in FIG. 1;

FIG. 3 is a cutaway view of a second structural element according to the invention;

FIG. 4 is a partial cutaway view of a first structure for a solar panel according to the invention;

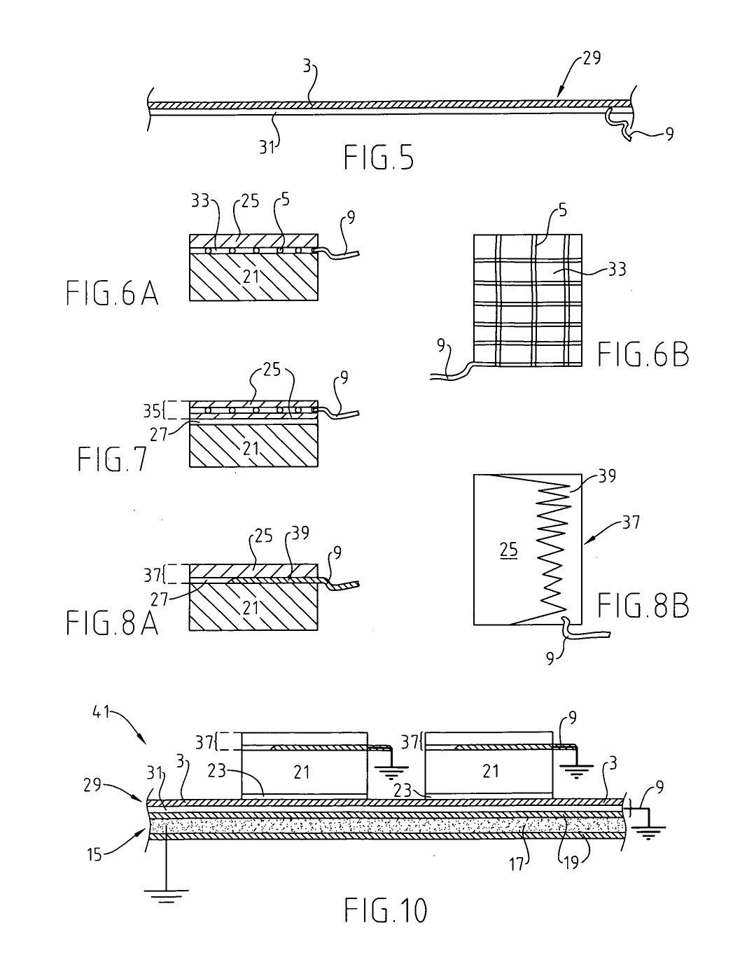

FIG. 5 is a cutaway view of a third structural element according to the invention;

FIGS. 6A and 6B show a cutaway view and a top view of a first photoelectric cell comprising a structural element according to the invention;

FIG. 7 is a cutaway view of a second cell comprising a structural element according to the invention;

FIGS. 8A and 8B show a cutaway view and a top view of a third cell comprising a structural element according to the invention;

FIG. 9 is an exploded perspective view of a fourth cell comprising a structural element according to the invention; and

FIG. 10 is a partial cutaway view of a second structure for a solar panel according to the invention.

FIGS. 1 to 5 and 9 will be considered first, which show different examples of structural elements according to the invention for supporting photoelectric cells.

Secondly, elements according to the invention for protecting photoelectric cells will be described.

FIGS. 1 and 2 show a first structural element 1 for a solar panel, comprising at least one layer of dielectric material 3.

The layer of dielectric material 3 can be a polyimide polymer such as that marketed under the name Kapton® or Upilex®.

The thickness of the layer of dielectric material 3 can be from 25 μm to 500 μm.

According to the invention, the structural element 1 comprises conductive means 5.

The conductive means 5 are formed by interlaced metal wires, forming a grid 5.

The grid 5 is positioned against the layer of dielectric material 3 so as to be in contact therewith, and is held there by an adhesive 7 in which it is embedded, the adhesive 7 constituting adhesion means.

The adhesive 7 can be the adhesive conventionally used for the adhesive bonding of the polyimide which is commonly found on Kapton® adhesive tapes.

In order to permit discharging of the charges which may accumulate on the layer of polyimide polymer, a conductive wire 9 is connected to the grid 5.

The conductive wire 9 may be any other conductive element.

The conductive wire 9 constitutes a connection means for connecting the grid 5 to the earth of the structure.

FIG. 3 shows another embodiment of a structural element 11 for a solar panel according to the invention.

The element 11 comprises two layers of dielectric material 3, each made of polyimide polymer.

The two layers 3 are superposed and are connected together by a layer of adhesive 7 in which there is embedded a grid 5, said layer of adhesive 7 being trapped between two layers 3 so that the stack of layers forms a so-called “sandwich” structure.

In a similar manner to the embodiment shown in FIGS. 1 and 2, the grid 5 is integral with a metal wire 9 forming a connection means for connecting the grid 5 to the earth of the structure.

FIG. 4 shows a structure 13 according to the invention comprising the structural element 11 shown in FIG. 3.

In addition to the structural element 11, the structure 13 comprises a base assembly 15 comprising a layer of conductive material 17 trapped between two stiffening layers 19.

The layer of conductive material 17 can be a sheet of aluminium 17 having a honeycomb structure.

The sheet of aluminium 17 is connected to the earth of the structure.

The stiffening layers 19 are each in the form of a layer comprising a mesh of carbon fibres trapped in a layer of epoxy adhesive.

The grid 5 of metal wires is connected to the sheet of aluminium 17 having a honeycomb structure by the conductive wire 9. The grid 5 may also be connected to the negative (−) pole of the solar cells.

The structure 13 also comprises photoelectric cells 21.

The photoelectric cells 21 are arranged on the layer of dielectric material 3, in a conventional manner, in a matrix configuration.

Only two photoelectric cells 21 have been shown in FIG. 4 in order to simplify understanding thereof.

The photoelectric cells 21 are fixed to the layer of dielectric material 3 by a layer of adhesive 23 which is silicone adhesive (the cell is fragile; silicone adhesive will be used rather than epoxy adhesive, which will be used more to bond rigid structures).

Each of the photoelectric cells 21 is covered with a sheet of protective glass 25, of dimensions substantially equal to those of the cells 21.

The sheets of protective glass 25 are held on the photoelectric cells by a layer of adhesive 27, which can be silicone adhesive.

FIG. 5 shows another variant of a structural element 29 according to the invention. The structural element 29 comprises a layer of dielectric material 3 and a layer of conductive material 31.

The layer of conductive material 31 is, for example, a metal coating deposited on one of the faces of the layer of dielectric material 3, in a manner known per se to the person skilled in the art.

Within the scope of this embodiment, the metal coating 31 is deposited on the entire surface of one of the faces of the layer of dielectric material 3.

A conductive wire 9 is connected to the layer of metal material 31 in order to connect the metal coating 31 to the earth of the structure.

FIGS. 6A, 6B, 7, 8A and 8B show other embodiments of structural elements according to the invention, according to which the sheet of protective glass 25 of the photoelectric cells 21, which itself constitutes a layer of dielectric material, is associated with means for discharging electric charges.

FIG. 6A shows a sheet of protective glass 25 on which there is positioned and fixed, on the side facing the cell 21, a grid of metal wires or conductors 5 connected to a conductive wire 9.

Preferably, the grid 5 is vacuum deposited directly on the glass. In a variant, the grid 5 can be held against or fixed to the sheet of glass 25 by being embedded in a layer of silicone adhesive 33.

The layer of silicone adhesive 33 also serves as a means for fixing the sheet of glass 25 to a photoelectric cell 21.

FIG. 7 shows yet another variant of a structural element for a solar panel according to the invention, according to which a protective element 35 for a cell 21 comprises two sheets of glass 25 connected by one of their faces by means of a layer of silicone adhesive 33 in which there is embedded a grid of conductive wires 5.

A conductive wire 9 is fixed to the grid 5 in order to connect the grid to the earth.

The element 35 is itself fixed to the surface of the photoelectric cell 21 by a layer of silicone adhesive 27 distributed on the free surface of the sheet of glass adjacent to the cell 21.

FIGS. 8A and 8B show yet another variant of a structural element for a solar panel according to the invention.

The protective element 37 of a photoelectric cell 21 comprises a sheet of protective glass 25.

On one of the surfaces of the sheet of glass 25, a metal coating or film 39 has been deposited punctually, that is to say on only part of the surface.

A conductive wire 9 is connected to the metal film 39 so that the structural element 37 can be connected to the earth thereof.

The element 37 so produced is fixed to the photoelectric cell 21 by a layer of silicone adhesive 27.

For reasons relating to the efficiency of the photoelectric cell 21, it is appropriate to produce the film 39 so that it covers as little of the cell 21 as possible.

For the purposes of understanding of the figures, the film 39 has deliberately been exaggerated.

It must be understood, however, that the coating or film must be as unintrusive as possible in order to alter the capacity of the cell 21 as little as possible.

FIG. 9 shows another variant in which the coating 39 is in the form of a metal comb which extends on one side of the sheet of glass 25. An identical metal comb 40 is produced on the upper face of the cell 21, which is facing, the opposite face of which has a metal coating 42. Accordingly, by superposing the two combs, the useful part of the cell is not covered. It is also possible to provide direct contact with a conductive plug through the silicone adhesive.

FIG. 10 shows a structure 41 according to the invention, comprising photoelectric cells 21 fixed by a layer of epoxy adhesive 23 to a structural element 29 as shown in FIG. 5.

The structural element 29 is fixed to a base assembly 15 as defined above, comprising three superposed layers of material, more particularly a layer of conductive material 17 trapped between two stiffening layers 19.

The layer of conductive material 17 is connected to the earth of the structure.

The photoelectric cells 21 of the structure 41 are each covered with a protective element 37 as shown in FIGS. 8A and 8B.

Each coating 39 of the elements 37 is connected to the earth of the structure by a conductive wire 9, so that the charges on the sheet of glass are discharged by the wire 9.

It will be understood from the preceding description how the invention permits the discharging of the charges which accumulate on a layer of dielectric component.

However, it must be understood that the invention is not limited to the use of specific materials such as those presented in the embodiments which have been described, such as polyimide polymer or epoxy or silicone adhesives.

In addition, according to another embodiment, the conductive means 5 form not a grid but a coil or spiral which is in contact with the layer of dielectric material 3 and is integral with an electrical connection means forming a connection means for connecting the conductive means to the earth of the structure.

1. Structural element for a solar panel, comprising at least one layer of dielectric material, comprising conductive means, which are in contact with said layer of dielectric material, and an electrical connection means for connecting the conductive means to the earth of said structure.

2. Structural element according to claim 1, wherein said conductive means comprise a grid of metal wires or conductors.

3. Structural element according to claim 2, wherein said metal grid is positioned against a surface of said layer of dielectric material and held by adhesion means, or is vacuum deposited.

4. Structural element according to claim 2, wherein said grid is arranged between two layers of dielectric material.

5. Structural element according to claim 1, wherein said conductive means comprise a conductive coating which covers a surface of said layer of dielectric material at least partially.

6. Structural element according to claim 1, wherein said layer of dielectric material is made of polyimide polymer.

7. Structural element according to claim 1, wherein said layer of dielectric material is a sheet of protective glass for a photoelectric cell.

8. Structural element according to claim 1, wherein said electrical connection means is a conductive element.

9. Structural for a solar panel, comprising at least one structural element according to claim 1.

10. Solar panel comprising a structure according to claim 9.
